(19) United States
(12) Patent Application Publication
(10) Pub. No.: US 2013/0154681 A1
(43) Pub. Date: Jun. 20, 2013

(54) SUBSTRATE INSPECTION JIG AND SUBSTRATE INSPECTION METHOD

(71) Applicants: Keishi Miyanishi, Kanagawa (JP); Yuji Miura, Kanagawa (JP); Shinji Nagai, Kanagawa (JP); Tomohiko Shiki, Kanagawa (JP); Tadayoshi Shibasaki, Kanagawa (JP); Hideo Watanabe, Kanagawa (JP); Katsuhiro Tanabe, Tokyo (JP); Hiroyuki Inakazu, Kanagawa (JP); Yasukazu Sadakane, Kanagawa (JP); Tomoko Kawakami, Kanagawa (JP)

(72) Inventors: Keishi Miyanishi, Kanagawa (JP); Yuji Miura, Kanagawa (JP); Shinji Nagai, Kanagawa (JP); Tomohiko Shiki, Kanagawa (JP); Tadayoshi Shibasaki, Kanagawa (JP); Hideo Watanabe, Kanagawa (JP); Katsuhiro Tanabe, Tokyo (JP); Hiroyuki Inakazu, Kanagawa (JP); Yasukazu Sadakane, Kanagawa (JP); Tomoko Kawakami, Kanagawa (JP)

(73) Assignee: RICOH COMPANY, LTD., Tokyo (JP)

(21) Appl. No.: 13/714,869

(22) Filed: Dec. 14, 2012

(30) Foreign Application Priority Data
Dec. 15, 2011 (JP) 2011-274497

(51) Int. Cl. G01R 1/04

(52) U.S. Cl. CPC G01R 1/0408
USPC 324/756.01; 324/763.01

(57) ABSTRACT

A substrate inspection jig for use in inspection of an electrical property of a printed board to be inspected on which an electronic component is mounted includes a spacer which is mounted on the printed board to be inspected, a conductive plate which is connected to the spacer, and is disposed along an arrangement direction of electrode terminals of the electronic component to be inspected, and a fastener which fastens the spacer on the printed board to be inspected, wherein the plate is disposed above the printed board to be inspected so as to avoid contact with the printed board to be inspected, and a predetermined potential of the printed board to be inspected is set to the plate through the spacer or/and the fastener.

### PRIORITY CLAIM

The present application is based on Japanese Patent Application No. 2011-126292, filed on Jun. 6, 2011 and Japanese Patent Application No. 2011-274497, filed on Dec. 15, 2011, and claims priority from Japanese Patent Application No. 2011-274497, the disclosure of which is hereby incorporated by reference in Its entirety.

### BACKGROUND

1. Field of the Invention

The present invention relates to a substrate inspection jig for use in the inspection of an electrical property of a printed board on which an electronic component such as an IC chip having an electrode terminal is mounted, and a substrate inspection method.

2. Description of the Related Art

In the inspection (measurement) of an electrical property of a printed board on which an IC chip (electronic component) having many electrode terminals (lead terminal) is mounted, a probe described in JP2001-33482A, for example, is directly brought into contact with an inspection point (wiring part of printed board and electrode terminal of IC chip).

A method of electrically bringing a pointed leading end of a short ground blade into contact with a sheet-like copper pad closely attached on an IC chip is known so as to reduce the effect of linking noise when inspecting an electrical property of an inspection point (connection portion between wiring portion of printed board and electrode terminal of IC chip) by directly bringing the above probe into contact with the inspection point as described in Non-Patent Document, for example, URL: http://cp, literature. agilent. com/litweb/pdf/5990-3930JAJAp.pdf. In addition, the base end side of the ground blade is electrically connected to the probe, and the copper pad is electrically connected to the ground on the printed board.

However, in the technique described in Non-Patent Document, it is necessary to closely attach the sheet-like copper pad on the IC chip while positioning the copper pad on the IC chip before the inspection with respect to each printed board to be inspected, resulting in deterioration in the inspection efficiency.

### SUMMARY

It is, therefore, an object of the present invention to provide a substrate inspection jig which can inspect an electrical property of a printed board on which an electronic component such as an IC chip having an electrode terminal is mounted with good workability, and a substrate inspection method using the substrate inspection jig.

In order to achieve the above object, one embodiment of the present invention provides a substrate inspection jig for use in inspection of an electrical property of a printed board to be inspected on which an electronic component is mounted, including: a spacer which is mounted on the printed board to be inspected; a conductive plate which is connected to the spacer, and is disposed along an arrangement direction of electrode terminals of the electronic component to be inspected; and a fastener which fastens the spacer on the printed board to be inspected, wherein the plate is disposed above the printed board to be inspected so as to avoid contact with the printed board to be inspected, and a predetermined potential of the printed board to be inspected is set to the plate through the spacer or/and the fastener.

One embodiment of the present invention also provides a substrate inspection method of inspecting an electrical property of a printed board to be inspected on which an electronic component is mounted, including the steps of preparing a substrate inspection jig including a spacer which is mounted on the printed board to be inspected, a conductive plate which is connected to the spacer and is disposed along an arrangement direction of electrode terminals of the electronic component, and a fastener which fastens the spacer on the printed board to be inspected; disposing the plate above the printed board to be inspected so as to avoid contact with the printed board to be inspected; and setting a predetermined reference potential of the printed board to be inspected to the plate through the spacer and/or the fastener by using the substrate inspection jig; and inspecting the electronic property of the printed board to be inspected with a potential of the plate as a reference.

One embodiment of the present invention also provides a substrate inspection method of inspecting an electrical property of a printed board to be inspected on which an electronic component is mounted, including: a step of attaching the substrate inspection jig as described above on the printed board to be inspected; a step of inspecting the electrical property of the printed board to be inspected with a potential of the plate as a reference; and a step of removing the printed board to be inspected from the substrate inspection jig after the inspection.

### BRIEF DESCRIPTION OF THE DRAWINGS

The accompanying drawings are included to provide further understanding of the invention, and are incorporated in and constitute a part of this specification. The drawings illustrate embodiments of the invention and, together with the specification, serve to explain the principle of the invention.

FIG. 1 is a perspective view illustrating a substrate inspection jig according to Embodiment 1 of the present invention.

FIG. 2 is a sectional view illustrating a structure which fastens a spacer to a printed board.

FIG. 3 is a perspective view illustrating a ground plate on one side of the printed board according to Embodiment 1.

FIG. 4 is a plan view illustrating the ground plate on one side of the printed board according to Embodiment 1.

FIG. 5 is a schematic side view illustrating a substrate inspection method using the substrate inspection jig according to Embodiment 1 of the present invention.

FIG. 6 is a schematic plan view illustrating the substrate inspection method using the substrate inspection jig according to Embodiment 1.

FIG. 7A is a perspective view illustrating a substrate inspection jig according to a modified example of Embodiment 1.

FIG. 7B is a perspective view illustrating a substrate inspection jig according to another modified example of Embodiment 1.

FIG. 8 is a perspective view illustrating a substrate inspection jig according to Embodiment 2 of the present invention.

FIG. 9 is a plan view illustrating a ground plate on one side of a printed board according to Embodiment 2.

FIGS. 10A, 10B are views each illustrating adjustment of a position of a plate fastener of the substrate inspection jig according to Embodiment 2. FIG. 10A is a view illustrating a state in which the plate fastener is moved on the side of a plate-moving section along a guide shaft, and FIG. 10B is a view illustrating a state in which the plate fastener is moved in a direction away from the plate-moving section.

FIG. 11A is a perspective view illustrating a substrate inspection jig according to a modified example of Embodiment 2.

FIG. 11B is a perspective view illustrating the substrate inspection jig according to another modified example of Embodiment 2.

FIG. 12 is a plan view illustrating grooves formed on the upper and lower surfaces of the plate-moving section of the substrate inspection jig at different pitches according to a modified example of the present invention.

### DETAILED DESCRIPTION OF THE PREFERRED EMBODIMENTS

Hereinafter, embodiments of the present invention will be described with reference to the drawings.

### Embodiment 1

FIG. 1 is a perspective view illustrating a substrate inspection jig 1 according to Embodiment 1 of the present invention. The substrate inspection jig 1 of the embodiment illustrated in FIG. 1 is used for inspecting (measuring) an electrical property of a printed board on which an electronic component such as an IC chip is mounted by using a probe having a known ground blade. The details will be described later.

As illustrated in FIG. 1, the substrate inspection jig 1 according to the present embodiment includes a conductive metal cylindrical spacer 2 which is placed near each of four corner portions on a rectangular printed board 10, and a conductive metal ground plate 3 which has contact with each spacer 2 in each corner portion of the printed board 10 and is arranged along each of the four sides of the printed board 10.

An IC chip 11 is mounted on the central portion of the printed board 10. A plurality of electrode terminals (lead terminals) electrically connected to a not-shown wiring portion formed on the printed board 10 is provided at predetermined pitches on each side surface of the IC chip 11.

In FIG. 1, the wiring portion, a wiring pattern, land section or the like, which are connected to each electrode terminal 11a of the IC chip 11 mounted on the printed board 10, are not illustrated. In FIG. 1, the electrode terminals 11a are provided only on the adjacent two side surfaces out of the four side surfaces of the 1C chip 11, but a plurality of electrode terminals is similarly provided on the other two side surfaces.

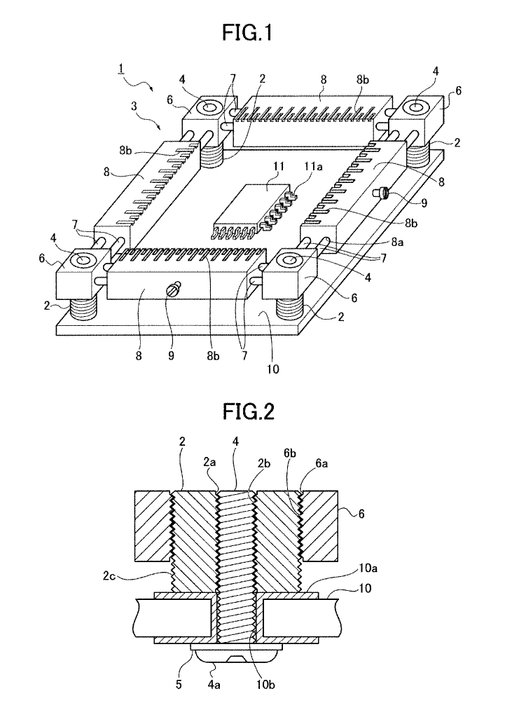

As illustrated in FIG. 2, a land section 10a having a ground pattern is provided on both surfaces of the printed board 10 near the corner portion. A through-hole 10b is formed in the central portion of the land section 10a. Each spacer 2 of the substrate inspection jig 1 is arranged in accordance with a position of each land section 10a of the printed board 10. A through-hole 2a having an inside screw groove (female screw) 2b is formed in the central portion of the spacer 2. The spacer 2 is provided on the land section 10a such that the through-hole 2a is communicated with the through-hole 10b. In addition, the spacer 2 includes on the outer periphery thereof an outside screw groove (male screw) 2c.

A conductive metal screw 4 which is inserted into the through-hole 10b from the back surface of the printed board 10 (the side opposite to the IC chip 11) is threadably mounted on the inside screw groove 2b of the through-hole 2a. A head portion 4a of the screw 4 is thereby pressed to the land section 10a on the back surface of the printed board 10 through a washer 5, so that the spacer 2 is fastened on the land section 10a on the front surface of the printed board 10.

As illustrated in FIGS. 1, 3, 4, the ground plate 3 includes four conductive plate fasteners 6 which are threadably mounted on the outer peripheries of the spacers 2, respectively, a pair of conductive cylindrical guide shafts 7 which are connected between the plate fasteners 6 facing each other along each side of the printed board 10, four conductive cuboid plate-moving sections 8, which have a guide hole 8a into which each guide shaft 7 is inserted, and are movably held along the axis line direction (arrow a direction in FIG. 4) of the guide shaft 7, and a plate-locking screw 9 which locks each plate-moving section 8 to one guide shaft 7. A pair of guide shafts 7 connected between the facing plate fasteners 6 is arranged in parallel. In FIG. 4, the IC chip on the printed board 10 is omitted.

A through-hole 6a having a screw groove 6b which is threadably mounted on the outside screw groove 2c of the spacer 2 is formed in the central portion of the plate fastener 6. With this configuration, by turning the spacer 2 right and left before threadably mounting the screw 4 on the inside screw groove 2b, the position of the height of the threadably mounted plate fastener 6 is changed, so that an interval between the printed board 10 and the plate fastener 6 can be appropriately adjusted.

The plate-moving section 8 can move to maintain a constant interval relative to each electrode terminal 11a arranged in the IC chip 11 by a pair of the guide shafts 7 which are inserted into the guide-hole 8a. A plurality of grooves 8b each having a predetermined width is arranged in the corner portion of the upper portion of each plate-moving section 8 on the side facing each electrode terminal 11a of the IC chip 11 (upper corner portion of plate-moving section 8) along the longitudinal direction of the plate-moving section 8 (side direction of the printed board 10) in accordance with the pitch distance of each electrode terminal 11a of the IC chip 11.

Each plate-locking screw 9 is threadably mounted on a not-shown screw hole having a screw groove formed inwardly from the outside side surface of the plate-moving section 8 (the face opposite to the IC chip 11), and the leading end portion of the plate-locking screw 9 is pressed to the guide shaft 7 by turning the plate-locking screw 9, so that the plate-moving section 8 can be locked such that the plate-moving section 8 does not move.

Each groove 8b is formed such that one end thereof opens at the corner portion and the other end thereof is grooved from the corner portion at a predetermined length in the direction orthogonal to the axis line direction of the guide shaft 7.

The width of each groove 8b is formed to be substantially equal to that of the electrode terminal 11a of the IC chip 11. Each groove 8b is provided such that the long groove and the short groove are alternately arranged.

Next, a substrate inspection method which inspects an electrical property of the printed board 10 on which the IC chip 11 is mounted by using the substrate inspection jig 1 according to the present embodiment will be described.

At first, as illustrated in FIG. 1, each spacer 2 of the substrate inspection jig 1 is placed on each land portion 10a of the printed board 10 on which the IC chip 11 is mounted. In this case, the interval between the threadably mounted plate fastener 6 and the printed board 10 can be adjusted by turning the spacer 2. In this way, an interval can be ensured to the plate-moving section 8 movably maintained in the guide shafts 7 connected between the facing plate fasteners 6 so as to avoid the contact with a not-shown electronic component on the printed board 10.

Then, as illustrated in FIG. 2, the screw 4 is inserted into the through-hole 10b from the back surface of the printed board 10 (the side opposite to the IC chip 11) through the washer 5, so that the screw 4 is threadably mounted on the screw groove 2b of the through-hole 2a. The head portion 4 of the screw 4 is thereby pressed to the land portion 10a on the back surface of the printed board 10 through the washer 5, and the spacer 2 is fastened on the land portion 10a on the front surface of the printed board 10, so that the entire substrate inspection jig 1 is fastened on the printed board 10 in a state such that it is positioned on the printed board 10.

As described above, the entire substrate inspection jig 1 including the guide shafts 7 and the plate-moving sections 8 operates as a ground by the contact of the conductive screw 4 and spacer 2 to the land section 10a (ground pattern) of the printed board 10.

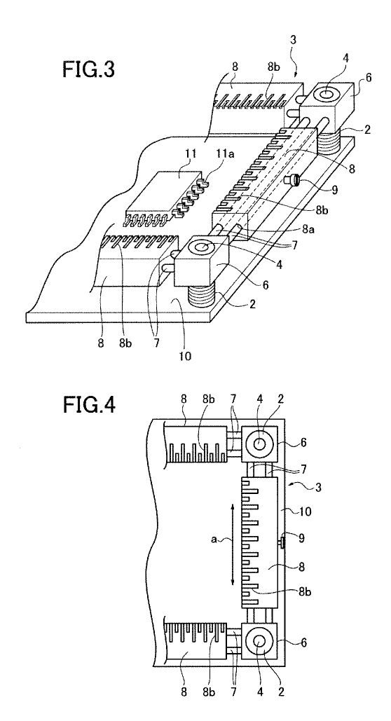

Then, as illustrated in FIGS. 3, 4, each plate-moving section 8 is moved along the axis line direction (arrow a direction in FIG. 4) of the guide shaft 7, such that the positions of each electrode terminal 11a of the IC chip 11 and each groove 8b of the plate-moving section 8 are adjusted to face each other in alignment. In this case, each groove portion 8b of the plate-moving section 8 is formed at a pitch distance which is the same as that of each electrode terminals 11a of the IC chip 11. With this configuration, each electrode terminal 11a of the IC chip 11 and each groove 8b of the plate-moving section 8 face in the same position.

After adjusting the position, the leading end portion of the plate-locking screw 9 is pressed to one guide shaft 7 by turning the plate-locking screw 9, so that the plate-moving section 8 is locked. By locking the plate-moving section 8 with the plate-locking screw 9, the positional shift between each electrode terminal 11a of the IC chip 11 and each groove 8b of the plate-moving section 8 can be prevented, and stable inspection (measurement) can be performed.

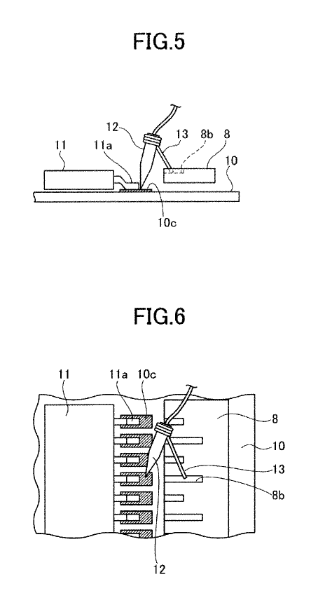

Then, as illustrated in FIGS. 5, 6, the pointed leading end portion of the probe 12 is brought into contact with the inspection point (the connection portion between the wiring portion 10c of the printed board 10 and the electrode terminal 11a of the IC chip 11), and the leading end portion of a ground blade 13 electrically connected to the probe 12 is brought into contact with the groove 8b of the plate-moving section 8, so as to inspect (measure) the electrical property of the printed board 10 on which the IC chip 11 is mounted by a not-shown device connected to the probe 12.

After inspecting (measuring) the electrical property of the printed board 10, the substrate inspection jig I is removed from the printed board 10 by turning each screw 4 in the direction opposite to the fastening direction so as to loosen each screw 4.

In the inspection (measurement), the substrate inspection jig I is fastened on the printed board 10, such that the substrate inspection jig 1 placed on the printed board 10 is disposed on the printed board 10, and each groove 8b formed in the plate-moving section 8 of the ground plate 3 is positioned to face each electrode terminal 11a of the IC chip 11. Therefore, according to the embodiment of the present invention, it is not necessary to closely attach a sheet-like copper pad on the IC chip while positioning the sheet-like copper pad on the IC chip as in the conventional technique; thus, the substrate can be effectively inspected.

Moreover, as illustrated in FIG. 6, for example, when bringing the probe 12 into contact with the fourth wiring portion 10c (electrode terminal 11a) from the end portion, the ground blade 13 is brought into contact with the groove 8b located in the position facing the fourth wiring portion 10c. In this way, the shift of the ground blade 13 in the inspection (measurement) is prevented, and the length of the ground blade 13 can be reduced. Accordingly, highly accurate inspection (measurement) can be effectively performed by controlling linking noise.

In this embodiment, a predetermined electric potential set in the ground blade 13 is a ground electric potential (0V), but it is not limited thereto, and an electric potential in addition to the ground electric potential can be used.

In addition, the respective grooves 8b are arranged such that the long groove and the short groove are alternately arranged. With this configuration, the groove number can be easily determined when counting each groove 8b from the end. Therefore, since the position of each groove 8b corresponds to the position of each electrode terminal 11a, it can be easily determined which target electrode terminal 11a is being inspected (measured).

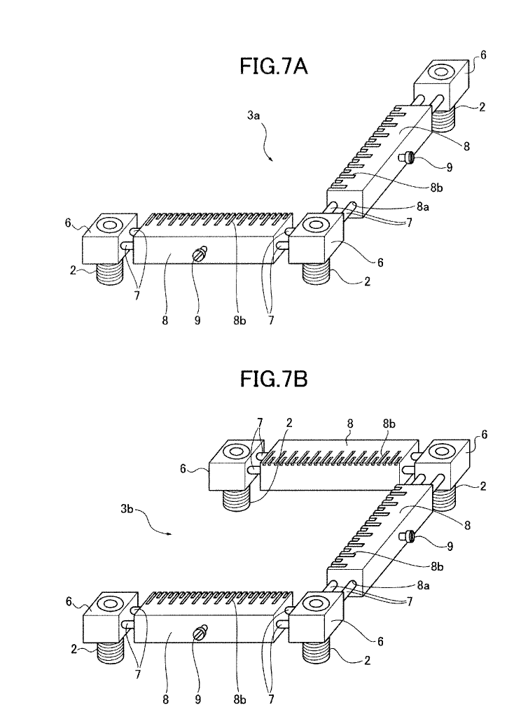

In the present embodiment, the four plate-moving sections 8 are arranged to be movable along the four sides of the printed board 10, but a ground plate 3a in which two plate-moving sections 8 are disposed in an L-shape as illustrated in FIG. 7A, and a ground plate 3b in which three plate-moving sections 8 are disposed in a U-shape as illustrated in FIG. 7B can be used according to the arrangement position of the electrode terminals provided in the IC chip.

Namely, in the ground plate 3a illustrated in FIG. 7A, the two plate-moving sections 8 are disposed in an L-shape in accordance with the electrode terminals arranged in the adjacent two sides of a not-shown IC chip. In the ground plate 3b illustrated in FIG. 7B, the three plate-moving sections 8 are disposed in a U-shape in accordance with the electrode terminals arranged in the three sides of a not-shown IC chip.

In addition to the above configurations, the spacer 2, plate fastener 6, guide shaft 7 and plate-moving section 8 can be arranged on only one side on the printed board 10, so as to similarly perform inspection (measurement) of the electrical property of the printed board 10. After the inspection (measurement) on one side, the spacer 2, plate fastener 6, guide shaft 7 and plate-moving section 8 are removed from the printed board 10 by loosening the screw 4, and the spacer 2, plate fastener 6, guide shaft 7 and plate-moving section 8 are sequentially arranged on the other sides, so as to similarly perform the inspection (measurement).

### Embodiment 2

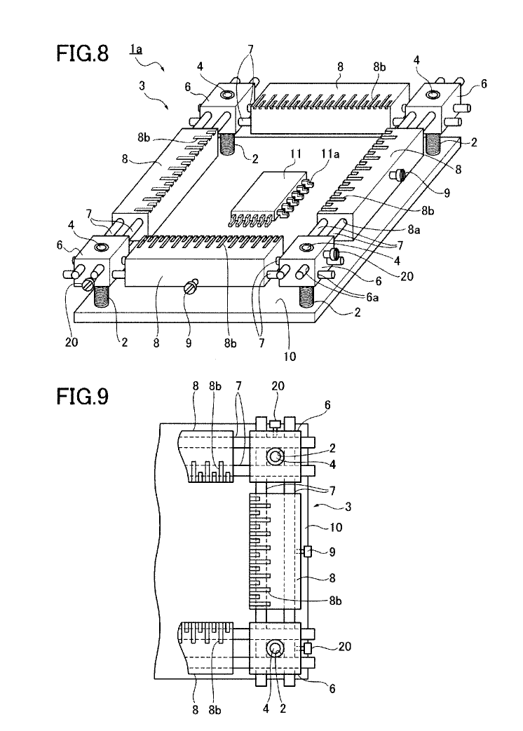

FIG. 8 is a perspective view illustrating a substrate inspection jig according to Embodiment 2 of the present invention. FIG. 9 is a plan view illustrating a ground plate on one side of a printed board. In addition, the same reference numbers are applied to the members having the same functions as those of the substrate inspection jig of Embodiment 1, so duplicated descriptions thereof will be omitted.

In Embodiment 1, a pair of conductive guide shafts 7 is connected between the facing plate fasteners 6, but in this embodiment, as illustrated in FIGS. 8, 9, a through-hole 6a (refer to FIG. 8) into which the guide shaft 7 is inserted is provided in each plate fastener 6, and the leading end portion of the guide shaft 7 is inserted into each plate fastener 6 positioned on both sides of each plate-moving section 8. Moreover, a guide shaft-locking screw 20 which locks one guide shaft 7 inserted into each through-hole 6a of each plate fastener 6 is provided in each plate fastener 6. The other configurations are similar to those of the substrate inspection jig of Embodiment 1. In FIG. 9, the IC chip on the printed board 10 is omitted.

In the substrate inspection jig 1a of the present embodiment, both end sides of each guide shaft 7 arranged to penetrate through the plate-moving section 8 extend to insert into the through-holes 6a formed in each plate fastener 6. Both end portions of each guide shaft 7 project from the through-hole 6a of each plate fastener 6.

The two through-holes 6a are formed on the upper side and the lower side of the plate fastener 6 near the outer periphery of the spacer 2. The two through-holes 6a formed on the upper side of the plate fastener 6 intersect with the two through-holes formed on the lower side of the plate fastener 6 such that the respective guide shafts 7 inserted into the plate fastener 6 from both directions orthogonal to each other do not have contact with each other in the plate fastener 6. With this configuration, a pair of the guide shafts 7 extending from one plate-moving section 8 is inserted into each through-hole 6a in the upper portion of the plate fastener 6, and a pair of the guide shafts 7 extending from the other plate-moving section 8 is inserted into each through-hole 6a in the lower side of the plate fastener 6.

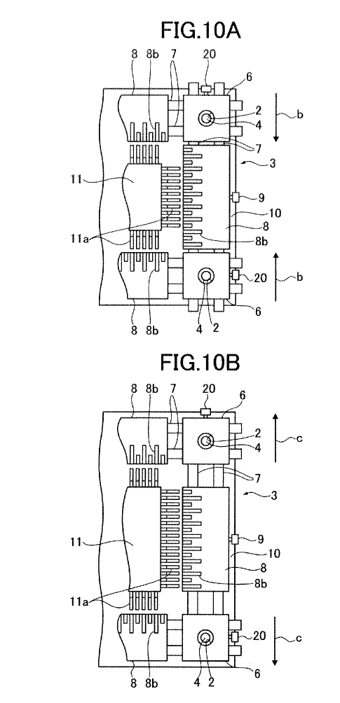

When measuring the electrical property of the printed board 10 on which the IC chip 11 is mounted by using the substrate inspection jig 1a according to the present embodiment, as illustrated in FIG. 10A, 10B, for example, the plate fastener 6 is moved in the arrow direction along the guide shaft 7 (arrow b direction in FIG. 10A and arrow c direction in FIG. 10B) in accordance with the position of each through-hole (not shown) of the land portion of the printed board 10.

In addition, FIG. 10A illustrates a case in which the size of the printed board 10 is small, and a not-shown through-hole is provided in a position close to both sides of the plate-moving section 8, and FIG. 10B is a case in which the size of the printed board 10 is larger than that in FIG. 10A, and a not-shown through-hole is provided in a position apart from the both sides of the plate-moving section 8.

After fastening the plate fastener 6 on the printed board 10 by the screw 4 threadably mounted on the spacer 2 in accordance with the position of the through-hole similar to Embodiment 1, the leading end portion of the guide shaft-locking screw 20 is pressed to one guide shaft 7 by turning the guide shaft-locking screw 20, so that the guide shaft 7 is locked to the plate fastener 6.

Then, by moving each plate-moving section 8 along the axis line direction of the guide shaft 7, the positions of each electrode terminal 11a of the IC chip 11 and each groove 8b of the plate-moving section 8 are adjusted such that each electrode terminal 11a and each groove 8b face each other in alignment. In this case, each groove 8b of the plate-moving section 8 is formed at the same pitch distance as that of each electrode terminal 11a of the IC chip 11. With this configuration, each electrode terminal 11a of the IC chip 11 and each groove 8b of the plate-moving section 8 face each other in the same position.

After adjusting the position, the leading end portion of the plate-locking screw 9 is pressed to one guide shaft 7 by turning the plate-locking screw 9, so that the plate-moving section 8 is locked to the guide shaft 7. By locking the plate-moving section 8 with the plate-locking screw 9, the positional shift between each electrode terminal 11a of the IC chip 11 and each groove 8b of the plate-moving section 8 can be prevented. Therefore, stable inspection (measurement) can be performed.

Then, similar to Embodiment 1, as illustrated in FIGS. 5, 6, the pointed leading end portion of the probe 12 has contact with the inspection point (the connection portion between the wiring portion 10c of the printed board 10 and the electrode terminal 11a of the IC chip 11), and the leading end portion of the ground blade 13 electrically connected to the probe 12 has contact with the groove 8b of the plate-moving section 8, so as to inspect (measure) the electrical property of the printed board 10 on which the IC chip 11 is mounted by a not-shown device connected to the probe 12.

After inspecting (measuring) the electrical property of the printed board 10, the substrate inspection jig 1a is removed from the printed board 10 by turning each screw 4 in the direction opposite to the fastening direction.

As described above, in the substrate inspection jig 1a of the present embodiment, each plate fastener 6 is moved along the axis line direction of the guide shaft 7, and is locked in an arbitrary position by the guide shaft-locking screw 20. With this configuration, when inspecting the electrical property of the printed board 10 having a different position of the through-hole (refer to FIG. 2) of the land portion, for example, the inspection can be performed by only one substrate inspection jig 1a by moving each plate fastener 6 along the guide shaft 7.

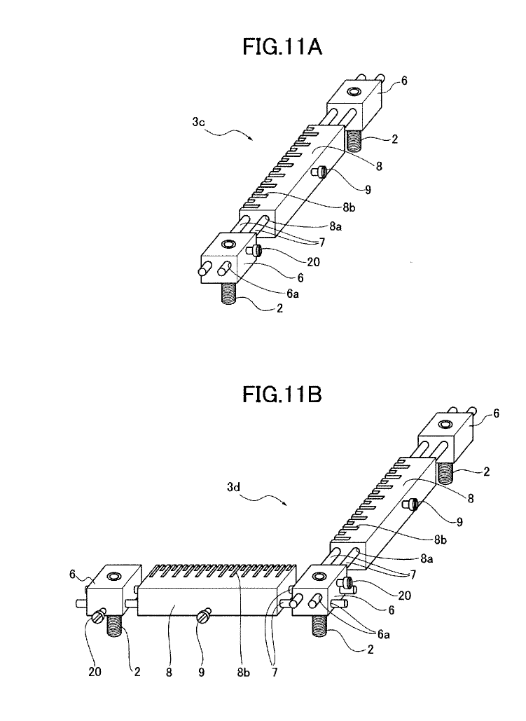

In the present embodiment, the four plate-moving sections 8 are arranged to be movable along the four sides of the printed board, but ground plates 3c, 3d as illustrated in FIGS. 11A, 11B, for example, can be used according to the arrangement position of the electrode terminals provided in the IC chip.

Namely, in the ground plate 3c in FIG. 11A, one plate-moving section 8 is linearly arranged according to the electrode terminals provided on one side of the not-shown IC chip. The plate fastener 6 is disposed on both sides of the plate-moving section 8, and two guide shafts 7 are inserted into the plate-moving section 8 and the plate fasteners 6.

In the ground plate 3d in FIG. 11b, the two plate-moving sections 8 are arranged in both directions orthogonal to each other according to the electrode terminals provided on the adjacent two sides of the not-shown IC chip. The plate fastener 6 is disposed on both sides of each plate-moving section 8, and two guide shafts 7 are inserted into the plate-moving section 8 and the plate fasteners 6. In addition, the two through-holes 6a are formed in the upper side and the lower side of the plate fastener 6 near the outer periphery of the spacer 2, and the two through-holes 6a in the upper side of the plate fastener 6 and the two through-holes 6a in the lower side of the plate fastener 6 intersect with each other such that the respective guide shafts 7 inserted from both directions orthogonal to each other do not have contact with each other in the plate fastener 6.

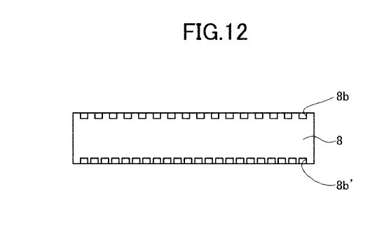

In the substrate inspection jig in each of Embodiments 1, 2, as illustrated in FIG. 12, grooves 8b and grooves 8b′ having pitches different from the pitches of the groove 8b can be formed near the corner portions of the upper portion and the lower portion of the plate-moving section 8 (near the corner portions of the upper portion and the lower portion on the side facing the terminal portions of the IC chip) along the longitudinal direction of the plate-moving section 8, respectively. In FIG. 12, the pitches of the grooves 8b are formed so as to be larger than those of the grooves 8b′.

As described above, by forming the grooves 8b and the grooves 8b′ having different pitches near the corner portions of the upper surface and the lower surface of the plate-moving section 8, the two printed boards on which IC chips each having different wiring pitches are mounted, respectively, can be inspected by a single substrate inspection jig by using the plate-moving section 8 upside down.

Moreover, the substrate inspection jig of Embodiments 1, 2 can be easily disposed on the printed board or can be easily removed from the printed board as described above. Since the inspection can be sequentially performed by one substrate inspection jig relative to a plurality of printed boards, the inspection costs per printed board can be reduced.

In Embodiment 1 (similar to Embodiment 2), both of the head portion 4a of the screw 4 and the spacer 2 electrically have contact with the land portion 10a of the printed board 10, but one of the head portion 4a of the screw 4 and the spacer 2 can electrically have contact with the land portion 10a of the printed board 10.

Moreover, in Embodiment 1 (similar to Embodiment 2), the spacer 2 is fastened to the land portion 10a of the printed board 10 by the screw 4, but the spacer 2 can be soldered to the land portion 10a of the printed board 10, or the spacer 2 can be fastened by inserting the spacer 2 into the through-hole 10b of the land portion 10a of the printed board 10.

In Embodiments 1, 2, the spacer 2 and the plate fastener 6 are separately formed, but the spacer 2 and the plate fastener 6 can be integrally formed if the height and position adjustments are not required. Furthermore, if a fastener which fastens the spacer 2 on the printed board 10 is a member which is pressed or fitted in the through-hole of the printed board 10, for example, the spacer 2 and the fastener can be integrally formed. In this embodiment, the spacer, plate fastener and fastener are not specifically limited as long as these include the above functions.

According to the substrate inspection jig and the substrate inspection method according to the present embodiments, it is not necessary to closely attach a sheet-like copper pad on an electronic component while positioning the sheet-like copper pad on the electronic component as in the conventional technique. Accordingly, the substrate inspection can be effectively performed.

Although the embodiments of the present invention have been described above, the present invention is not limited thereto. It should be appreciated that variations may be made in the embodiments described by persons skilled in the art without departing from the scope of the present invention.

What is claimed is:

1. A substrate inspection jig for use in inspection of an electrical property of a printed board to be inspected on which an electronic component is mounted, comprising:
a spacer which is mounted on the printed board to be inspected;
a conductive plate which is connected to the spacer, and is disposed along an arrangement direction of electrode terminals of the electronic component to be inspected; and
a fastener which fastens the spacer on the printed board to be inspected,
wherein the plate is disposed above the printed board to be inspected so as to avoid contact with the printed board to be inspected, and a predetermined potential of the printed board to be inspected is set to the plate through the spacer or/and the fastener.

2. The substrate inspection jig according to claim 1, wherein the spacer has a conductive property, and has contact with a land portion having a reference potential on the printed board to be inspected.

3. The substrate inspection jig according to claim 1, wherein
the spacer includes on an outer periphery thereof a male screw,
the male screw is threadably mounted on a female screw formed in the plate, and
a height of the threadably mounted plate from the printed board to be inspected is adjusted by rotating the spacer.

4. The substrate inspection jig according to claim 1, wherein the spacer is disposed on both end sides relative to the plate.

5. The substrate inspection jig according to claim 1, wherein
the fastener includes a metal screw which is threadably mounted on a female screw formed in the spacer through a hole from a back surface opposite to a surface provided with the electronic component of the printed board to be inspected, so as to fasten the spacer on the printed board to be inspected, and
a head portion of the metal screw has contact with a land portion having a reference potential formed around the hole on the back surface of the printed board to be inspected, so that a potential of the plate is set through the spacer or the head portion of the metal screw has direct contact with the plate, so that the potential of the plate is set.

6. The substrate inspection jig according to claim 1, wherein
the plate includes a plate fastener electrically connected to the spacer, a conductive guide section having an end portion connected to the plate fastener, and disposed along the arrangement direction of the electrode terminals of the electronic component, a conductive substantially cuboid plate-moving section which is movable along the arrangement direction of the electrode terminals by sliding the guide section, and a plate-locking section which locks the plate-moving section to the guide section in an arbitrary position.

7. The substrate inspection jig according to claim 1, wherein
the plate includes a plate fastener electrically connected to the spacer, a conductive guide section having an end portion connected to penetrate through the plate fastener, and disposed along the arrangement direction of the electrode terminals of the electronic component, a conductive substantially cuboid plate-moving section which is movable along the arrangement direction of the electrode terminals by sliding the guide member, a plate-locking section which locks the plate-moving section to the guide section in an arbitrary position, and a guide locking section which locks the guide section to the plate fastener in an arbitrary position.

8. The substrate inspection jig according to claim 6, wherein
the plate fastener is disposed such that at least two guide sections are orthogonal to each other, and
the two guide sections are held in the plate fastener disposed to face a corner portion of two orthogonal sides of the electronic component to be inspected, so that the plate-moving section is movable along the two sides.

9. The substrate inspection jig according to claim 8, wherein the plate fastener is disposed in a square shape such that the guide sections are orthogonal to each other relative to each plate fastener disposed corresponding to four corner portions of the electronic component to be inspected, so that the plate-moving section is movable along four sides of the electronic component.

10. The substrate inspection jig according to any one of claim 6, wherein a plurality of grooves each having a predetermined width is arranged in a corner portion of an upper portion on a side facing the electrode terminals of the electrode component in the plate-moving section according to pitches of the electrode terminals along the guide section sliding direction.

11. The substrate inspection jig according to claim 10, wherein grooves having pitches different from the pitches of the grooves formed in the corner portion of the upper portion in the plate-moving section are formed in a corner portion of a lower portion on the side facing the electrode terminals of the electronic component in the plate-moving section along the guide section sliding direction.

12. The substrate inspection jig according to claim 10, wherein one end of the groove opens at the corner portion and the other end of the groove is grooved at a predetermined length from the corner portion in the direction orthogonal to the guide section sliding direction.

13. A substrate inspection method of inspecting an electrical property of a printed board to be inspected on which an electronic component is mounted, comprising the steps of
preparing a substrate inspection jig including a spacer which is mounted on the printed board to be inspected, a conductive plate which is connected to the spacer and is disposed along an arrangement direction of electrode terminals of the electronic component, and a fastener which fastens the spacer on the printed board to be inspected,
disposing the plate above the printed board to be inspected so as to avoid contact with the printed board to be inspected, and setting a predetermined potential of the printed board to be inspected to the plate through the spacer and/or the fastener by using the substrate inspection jig, and
inspecting the electronic property of the printed board to be inspected with a potential of the plate as a reference.

14. A substrate inspection method of inspecting an electrical property of a printed board to be inspected on which an electronic component is mounted, comprising:
a step of attaching the substrate inspection jig according to claim 1 on the printed board to be inspected,
a step of inspecting the electrical property of the printed board to be inspected with a potential of the plate as a reference, and
a step of removing the printed board to be inspected from the substrate inspection jig after the inspection.
